(19) United States
(12) Patent Application Publication
(10) Pub. No.: US 2023/0130461 A1
(43) Pub. Date: Apr. 27, 2023

(54) MICRO-LED DISPLAY PANEL AND MANUFACTURING METHOD THEREOF, AND DISPLAY DEVICE

(71) Applicant: Wuhan China Star Optoelectronics Technology Co., Ltd., Wuhan, Hubei (CN)

(72) Inventor: Li HU, Wuhan, Hubei (CN)

(73) Assignee: Wuhan China Star Optoelectronics Technology Co., Ltd., Wuhan, Hubei (CN)

(21) Appl. No.: 16/975,724

(22) PCT Filed: Jun. 19, 2020
(86) PCT No.: PCT/CN2020/097149

§ 371 Date: Aug. 26, 2020

(30) Foreign Application Priority Data
Jun. 10, 2020 (CN) 202010525366.6

(51) Int. Cl. G06F 3/044; H01L 33/36

(52) U.S. Cl. CPC G06F 3/0446; H01L 33/36; G09G 3/32

(57) ABSTRACT

The present application provides a micro-LED display panel, which includes a plurality of micro-LEDs; and an array substrate, including a first metal layer including a plurality of first connection electrodes and a plurality of second connection electrodes, wherein at least one of the plurality of first connection electrodes and the plurality of second connection electrodes are reusable electrodes, and each of the reusable electrodes drives a corresponding micro-LED to emit light at a display stage; and wherein each of the reusable electrodes is reused as a touch control electrode at a touch control stage.

### FIELD OF THE DISCLOSURE

The present application relates to display panel technologies, and more particularly to a micro-LED display panel and manufacturing method thereof, and a display device.

### DESCRIPTION OF RELATED ARTS

Micro light-emitting diode (micro-LED) display panels have advantages of long lifespan, high brightness, excellent luminous efficiency and low power consumption. With rapid development of display technologies, touch control technologies have been used as an indispensable part of display products. However, touch control components and display components of current micro-LED display panels are independent from each other and are laminated one on the other. This results in a large thickness of a touch display structure of the micro-LED display panel, thereby narrowing the scope of application of the micro-LED display panel.

### Technical Problems

Embodiments of the present application provide a micro-LED display panel with an In-Cell touch control structure, capable of reducing the thickness and cost of the micro-LED display panel, thereby widening the scope of application of the micro-LED display panel.

### Technical Solutions

A micro light-emitting diode (micro-LED) display panel, including:

a plurality of micro-LEDs; and

an array substrate, including a first metal layer that includes a plurality of first connection electrode and a plurality of second connection electrodes, each of the first connection electrodes and a corresponding second connection electrode connecting to a corresponding micro-LED,

wherein at least one of the plurality of first connection electrodes and the plurality of second connection electrodes are reusable electrodes, and each of the reusable electrodes drives the corresponding micro-LED to emit light at a display stage; and

wherein each of the reusable electrodes is reused as a touch control electrode at a touch control stage.

A method for manufacturing a micro light-emitting diode (micro-LED) display panel, including:

forming a third metal layer at a side of a substrate, wherein the third metal layer includes a source and a drain of a thin-film transistor;

forming a second insulating layer on the third metal layer, wherein the second insulating layer includes a first via hole;

forming a second metal layer on the second insulating layer, wherein the second metal layer includes a plurality of touch control connection electrodes and a plurality of touch control traces;

forming a first insulating layer on the second metal layer, wherein the first insulating layer includes a second via hole and a third via hole, and orthographic projection of the second via hole on the substrate at least partially overlaps with orthographic projection of the first via hole on the substrate;

forming a first metal layer on the first insulating layer, wherein the first metal layer includes a plurality of first connection electrodes and a plurality of second connection electrodes, the first connection electrode connects to the source or the drain of the thin-film transistor via the first via hole and the second via hole, at least one of the plurality of first connection electrodes and the plurality of second connection electrodes are reusable electrodes, each of the reusable electrodes drives a corresponding micro-LED to emit light at a display stage, each of the reusable electrodes is reused as a touch control electrode at a touch control stage, each touch control electrode includes some of the reusable electrodes connected to each other, each of the touch control connection electrodes is connected between two corresponding reusable electrodes, and the touch control traces connect to the touch control connection electrodes corresponding to the touch control electrodes; and

mounting micro-LEDs such that each of the first connection electrodes and a corresponding second connection electrode connect to a corresponding micro-LED.

The present application further provides a display device, including a micro light-emitting diode (micro-LED) display panel, which includes:

a plurality of micro-LEDs; and

an array substrate, including a first metal layer that includes a plurality of first connection electrode and a plurality of second connection electrodes, each of the first connection electrodes and a corresponding second connection electrode connecting to a corresponding micro-LED,

wherein at least one of the plurality of first connection electrodes and the plurality of second connection electrodes are reusable electrodes, and each of the reusable electrodes drives the corresponding micro-LED to emit light at a display stage; and

wherein each of the reusable electrodes is reused as a touch control electrode at a touch control stage.

Beneficial Effects

The beneficial effects of the present application are described as follows. The present application provides a micro-LED display panel with an In-Cell touch control structure. By integrating a touch function into the micro-LED display panel without a need of additional lamination with touch control components, the thickness and cost of the micro-LED display panel can be reduced, thereby widening the scope of application of the micro-LED display panel.

### DESCRIPTION OF DRAWINGS

FIG. 1 is a sectional view of a micro-LED display panel provided in an embodiment of the present application.

FIG. 2 is a sectional view of a micro-LED display panel provided in an embodiment of the present application.

FIG. 3 is a sectional view of a micro-LED display panel provided in an embodiment of the present application.

FIG. 4 is a top view of a touch control electrode of a micro-LED display panel provided in an embodiment of the present application.

FIG. 5 is a top view of a touch control electrode of a micro-LED display panel provided in an embodiment of the present application.

FIG. 6 is a top view of touch control electrodes and touch control traces of a micro-LED display panel provided in an embodiment of the present application.

FIG. 7 is a schematic diagram illustrating a display device provided in an embodiment of the present application.

### DESCRIPTION OF EMBODIMENTS OF THE DISCLOSURE

The technical solutions in the embodiments of the present application will be clearly and completely described below with reference to appended drawings of the embodiments of the present application. Obviously, the described embodiments are merely a part of embodiments of the present application and are not all of the embodiments. Based on the embodiments of the present application, all the other embodiments obtained by those of ordinary skill in the art without making any inventive effort are within the scope the present application.

In the description of the present application, it is to be understood that the terms “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise” and the like indicated orientation or positional relationship are based on the relationship of the position or orientation shown in the drawings, which is only for the purpose of facilitating description of the present application and simplifying the description, but is not intended to or implied that the device or element referred to must have a specific orientation, and be constructed and operated in a particular orientation. Therefore, it should not be construed as a limitation of the present application. In addition, the terms “first” and “second” are used for descriptive purposes only, and should not be taken to indicate or imply relative importance, or implicitly indicate the indicated number of technical features. Thus, by defining a feature with “first” or “second”, it may explicitly or implicitly include one or more features. In the description of the present application, “a plurality” means two or more unless explicitly defined.

In the description of the present application, it should be noted that unless otherwise explicitly specified or limited, the terms “installed”, “connected”, and “connection” should be construed broadly, for example, a fixed connection, a removable connection, or integrally connected. These terms may be directed to a mechanical connection, and may also be directed to an electrical connection or communication. Moreover, these terms can be directed to “directly attached”, “indirectly connected” through an intermediate medium, and may be directed to “internally communicated” with two components or the “interaction relationship” between two components. For persons skilled in the art, they can understand the specific meaning of the terms in the present application based on specific conditions.

In the present application, unless specified or limited otherwise, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “above,” or “on top of” a second feature may include an embodiment in which the first feature is right or obliquely “on,” “above,” or “on top of” the second feature, or just means that the first feature is at a height higher than that of the second feature; while a first feature “below,” “under,” or “on bottom of a second feature may include an embodiment in which the first feature is right or obliquely “below,” “under,” or “on bottom of” the second feature, or just means that the first feature is at a height lower than that of the second feature.

The following disclosure provides a plurality of different embodiments or examples to implement different structures of this application. To simplify the disclosure of this application, the following describes components and settings in particular examples. Certainly, the examples are merely for illustrative purposes, and are not intended to limit this application. In addition, in this application, reference numerals and/or reference letters may be repeated in different examples. This repetition is for the purpose of simplicity and clarity, and does not in itself indicate a relationship between the various embodiments and/or settings that are discussed. In addition, this application provides examples of various particular processes and materials, but a person of ordinary skill in the art will recognize that other processes and/or materials may be applied and/or used.

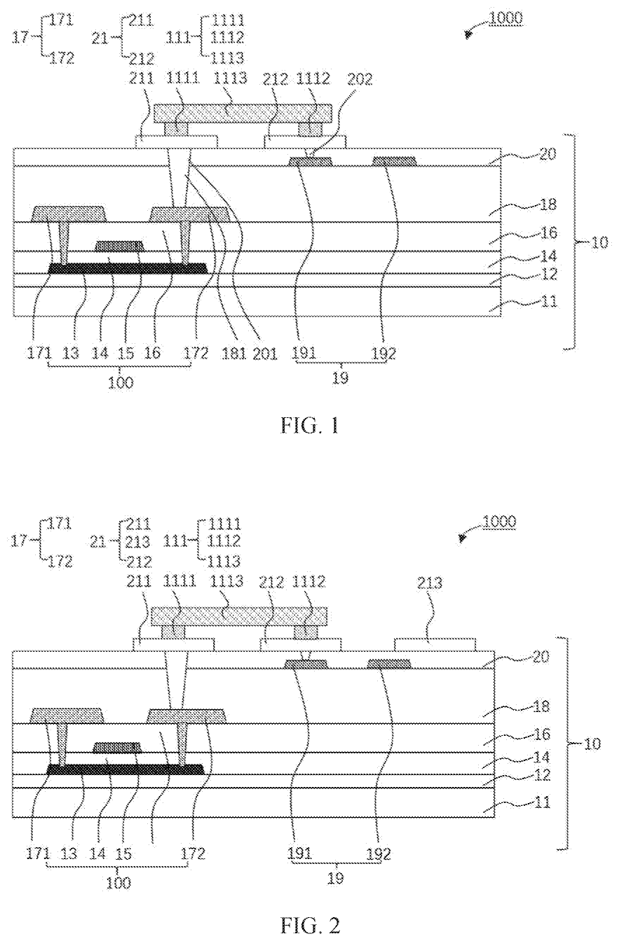

Referring to FIGS. 1 to 6, an embodiment of the present application provides a micro light-emitting diode (micro-LED) display panel 1000, which includes a plurality of micro-LEDs 111; and an array substrate 10, including a first metal layer 21 that includes a plurality of first connection electrode 211 and a plurality of second connection electrodes 212, each of the first connection electrodes 211 and a corresponding second connection electrode 212 connecting to a corresponding micro-LED 111, wherein at least one of the plurality of first connection electrodes 211 and the plurality of second connection electrodes 212 are reusable electrodes, and each of the reusable electrodes drives the corresponding micro-LED 111 to emit light at a display stage; and wherein each of the reusable electrodes is reused as a touch control electrode at a touch control stage.

The beneficial effects of the present application are described as follows. By integrating a touch function into the micro-LED display panel without a need of additional lamination with touch control components, the thickness and cost of the micro-LED display panel can be reduced, thereby widening the scope of application of the micro-LED display panel.

Specifically, the array substrate 10 includes a thin-film transistor 100, for example. The thin-film transistor 100 includes an active layer 13, a gate insulating layer 14, a gate 15, an insulating interlayer 16, a source 171 (or a source 172), a drain 172 (or a drain 171), and the first connection electrode 211 electrically connected to the source 171 (or the source 172) or the drain 172 (or the drain 171) of the thin-film transistor 100. The micro-LED 111 includes a first mounting electrode 1111, a second mounting electrode 1112 and a micro-LED body 1113. The first mounting electrode 1111 can be an anode or a cathode of the micro-LED 111; the second mounting electrode 1112 can be a cathode or an anode of the micro-LED 111. One of the first connection electrode 211 and the second connection electrode 212 connects to the source 171 (or the source 172) or the drain 172 (or the drain 171) of the thin-film transistor 100. As shown in FIGS. 1 to 3, the first mounting electrode 1111 is electrically connected to the first connection electrode 211 and the second mounting electrode 1112 is electrically connected to the second connection electrode 212. It is noted that the structure of the array substrate 10 or the thin-film transistor 100 is illustrated in the present application by using an example but the present application is not limited thereto.

Specifically, at least one of the plurality of first connection electrodes 211 and the plurality of second connection electrodes 212 are reusable electrodes. That is, a time-sharing multiplexing technology is adopted for each reusable electrode to drive a corresponding micro-LED 111 to emit light at the display stage and for each reusable electrode to be reused as a touch control electrode at the touch control stage to realize a touch control function. For example, this specifically includes utilizing a driving module to divide each frame into a display stage and a touch control stage; at the display stage, providing, by the driving module, display signals for the reusable electrodes; and at the touch control stage, providing, by the driving module, touch control signals for the reusable electrodes. Each micro-LED 111 includes the first mounting electrode 1111 and the second mounting electrode 1112. The array substrate 10 includes the first connection electrode 211 and the second connection electrode 212 that correspondingly connect to each micro-LED 111. The first connection electrode 211 and/or the second connection electrode 212 that acts as the reusable electrode can drive the micro-LED 111 connected thereto at the display stage.

Specifically, the micro light-emitting diode 111 includes a micro-LED but is not limited thereto.

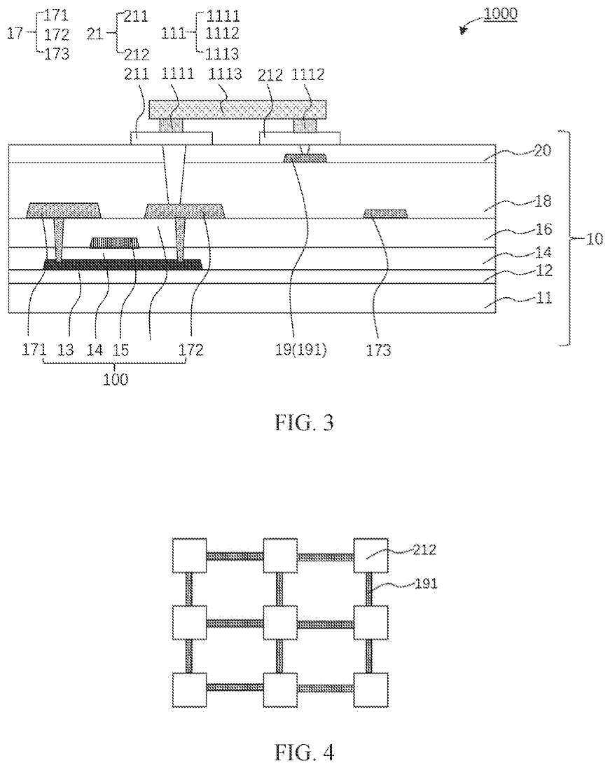

Referring to FIGS. 1 and 3, in some embodiments, at the touch control stage, at least a part of the plurality of the second connection electrodes 212 are reused as the touch control electrodes and the plurality of first connection electrodes 211 are not reused as the touch control electrodes.

Referring to FIGS. 1 and 3, in some embodiments, at the touch control stage, at least one classification of the plurality of first connection electrodes 211 and the plurality of the second connection electrodes 212 are reused as the touch control electrodes and the other one classification of the plurality of first connection electrodes 211 and the plurality of the second connection electrodes 212 are not reused as the touch control electrodes.

Specifically, the plurality of second electrodes include one part that is reused as the touch control electrodes or one part that is not reused as the touch control electrode, for example. All the plurality of second electrodes are reusable electrodes, for example. By reusing one classification of the plurality of first connection electrodes 211 and the plurality of second connection electrodes 212 as the touch control electrodes, manufacturing processes are simplified without a need to additionally manufacture the touch control electrodes.

Referring to FIGS. 1 and 3, in some embodiments, at the touch control stage, both the plurality of first connection electrodes 211 and the plurality of second connection electrodes 212 are reused as the touch control electrodes.

Specifically, all the plurality of first connection electrodes 211 and the plurality of second connection electrodes 212 are reusable electrodes. That is, a time-sharing multiplexing technology is adopted for each reusable electrode to drive a corresponding micro-LED 111 to emit light at the display stage and for each reusable electrode to be reused as a touch control electrode at the touch control stage to realize a touch control function. By reusing both the plurality of first connection electrodes 211 and the plurality of second connection electrodes 212 as the touch control electrodes, manufacturing processes are simplified without a need to additionally manufacture the touch control electrodes.

In some embodiments, the touch control electrodes include sensing touch control electrodes and receiving touch control electrodes, and at the touch control stage, at least a part of the plurality of first connection electrodes 211 are reused as the sensing touch control electrodes and at least a part of the plurality of second connection electrodes 212 are reused as the receiving touch control electrodes.

Specifically, a structure with an In-Cell touch control ability belongs to mutual-capacitive-type touch control, for example. The touch control electrodes include the sensing touch control electrodes and the receiving touch control electrodes. For example, the first connection electrodes 211 are reused as the sensing touch control electrodes and the second connection electrodes 212 are reused as the receiving touch control electrodes. For example, the second connection electrodes 212 are reused as the sensing touch control electrodes and the first connection electrodes 211 are reused as the receiving touch control electrodes. It is noted that the plurality of first connection electrodes 211 may be reused totally or partially and the plurality of second connection electrodes 212 may be reused totally or partially. Deployment for In-Cell mutual-capacitive-type touch control is illustrated in the present embodiment.

In some embodiments, the touch control electrodes include the sensing touch control electrodes and the receiving touch control electrodes, and at the touch control stage, at least a part of the plurality of first connection electrodes 211 and the plurality of the second connection electrodes 212 are reused as the sensing touch control electrodes and the receiving touch control electrodes.

Specifically, a structure with an In-Cell touch control ability belongs to mutual-capacitive-type touch control, for example. The touch control electrodes include the sensing touch control electrodes and the receiving touch control electrodes. For example, the first connection electrodes 211 are reused as the sensing touch control electrodes and the receiving touch control electrodes. For example, the second connection electrodes 212 are reused as the sensing touch control electrodes and the receiving touch control electrodes. It is noted that the plurality of first connection electrodes 211 may be reused totally or partially and the plurality of second connection electrodes 212 may be reused totally or partially. Deployment for In-Cell mutual-capacitive-type touch control is illustrated in the present embodiment.

Referring to FIG. 2, in some embodiments, the first metal layer 21 further includes third touch control electrodes 213.

Specifically, the third touch control electrodes 213 may be disposed between the first connection electrodes 211, between the second connection electrodes 212, or between the first connection electrodes 211 and the second connection electrodes 212. The third touch control electrodes 213 as well as the reused first connection electrodes 211 or/and second connection electrodes 212 may construct the touch control electrodes. The deployment of third touch control electrodes 213 can assist the reusable electrodes in realizing the touch control function and improving touch control performance.

In some embodiments, it may dispose the third touch control electrodes 213 only. Meanwhile, the first connection electrodes 211 and the second connection electrodes 212 may not be reused as the touch control electrodes. The touch control function can be realized as long as having the deployment of third touch control electrodes 213. For example, in a mutual-capacitive-type touch control structure, the third touch control electrodes 213 are deployed as the sensing touch control electrodes and the receiving touch control electrodes. For example, in a self-capacitive-type touch control structure, the third touch control electrodes 213 are deployed as the touch control electrodes. When only the third touch control electrodes 213 are deployed as the touch control electrodes, it can also realize a better touch control function. It is another type of deployment of In-Cell touch control.

In some embodiments, each touch control electrode in above embodiments may be set to have one first connection electrode 211 or/and one second connection electrode 212.

In some embodiments, each touch control electrode in above embodiments may be set to have one first connection electrode 211 or/and one second connection electrode 212, and one third touch control electrode.

In some embodiments, each touch control electrode in above embodiments may be set to have one third connection electrode 213.

In some embodiments, each touch control electrode includes one reusable electrode.

Specifically, each touch control electrode includes one first connection electrode 211 or/and one second connection electrode 212 that act as the reusable electrodes, for example.

In some embodiments, each touch control electrode includes one reusable electrode and the third touch control electrode 213.

Specifically, each touch control electrode includes one first connection electrode 211 or/and one second connection electrode 212 that act as the reusable electrodes, and one third touch control electrode 213.

In some embodiments, each touch control electrode includes one third touch control electrode 213.

Referring to FIG. 4, in some embodiments, each touch control electrode includes some of the reusable electrodes connected to each other.

Specifically, for example, when the reusable electrodes are one classification of the first connection electrodes 211 and the second connection electrodes 212, each touch control electrode includes a plurality of first connection electrodes 211; alternatively, each touch control electrode includes a plurality of second connection electrodes 212.

Specifically, for example, when the reusable electrodes are two classifications of the first connection electrodes 211 and the second connection electrodes 212, each touch control electrode includes a plurality of first connection electrodes 211 or/and a plurality of second connection electrodes 212.

Specifically, for example, when the reusable electrodes are two classifications of the first connection electrodes 211 and the second connection electrodes 212, each touch control electrode includes one first connection electrode 211 and a plurality of second connection electrodes 212; alternatively, each touch control electrode includes a plurality of first connection electrodes 211 and one second connection electrode 212.

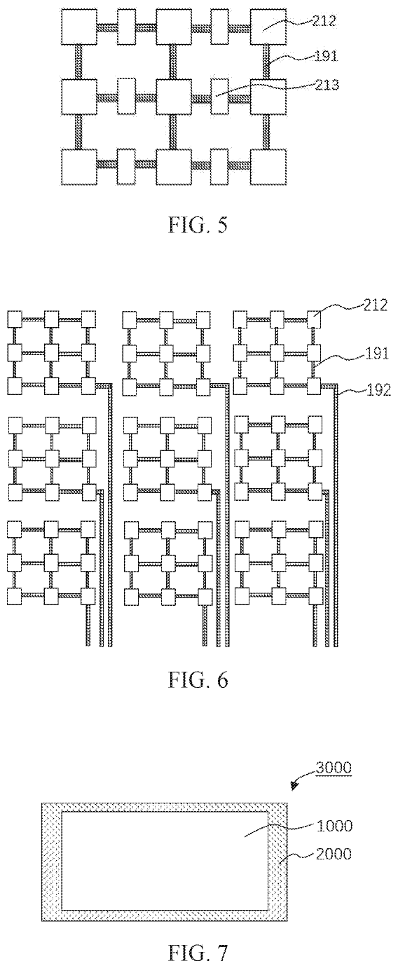

Referring to FIG. 5, in some embodiments, each touch control electrode includes one or more reusable electrodes and one or more third touch control electrodes 213 that are connected to each other.

In some embodiments, each touch control electrode includes a plurality of third touch control electrodes 213 connected to each other.

It is noted that the number of each of the first connection electrodes 211, the second connection electrodes 212 and the third touch control electrodes 213 for each touch control electrode is illustrated in above embodiments but the present application is not limited to the number of the reusable electrodes and the third touch control electrodes that are included in each touch control electrode. There are many ways to deploy the touch control electrodes and it may be chosen according to the needs of display panel design to enlarge the scope of possible In-Cell touch control structures and the scope of application thereof.

Referring to FIGS. 1 to 5, in some embodiments, the array substrate 10 includes a substrate 11 and a second metal layer 19. The second metal layer is located between the substrate 11 and the first metal layer 21. A first insulating layer 20 is provided between the first metal layer 21 and the second metal layer 19. The second metal layer 19 includes a plurality of touch control connection electrodes 191. Each of the touch control connection electrodes 191 is connected between two corresponding reusable electrodes.

Specifically, each touch control electrode includes a plurality of first connection electrodes 211 or/and a plurality of second connection electrodes 212, for example. In a same touch control electrode, the first connection electrodes 211 or/and the second connection electrodes 212 are connected as a whole using the touch control connection electrode 191.

Referring to FIGS. 1 to 5, in some embodiments, the array substrate 10 includes a substrate 11 and a second metal layer 19. The second metal layer is located between the substrate 11 and the first metal layer 21. A first insulating layer 20 is provided between the first metal layer 21 and the second metal layer 19. The second metal layer 19 includes a plurality of touch control connection electrodes 191. Each of the touch control connection electrodes 191 is connected to two corresponding reusable electrodes, or a corresponding reusable electrode and the third touch control electrode 213, or two corresponding third touch control electrodes 213.

Specifically, each touch control electrode includes a plurality of first connection electrodes 211 or/and a plurality of second connection electrodes 212, and a plurality of third touch control electrodes 213, for example. The first connection electrodes 211 or/and the second connection electrodes 212, and the third touch control electrodes 213 are connected as a whole using the touch control connection electrode 191.

Specifically, each touch control electrode includes a plurality of third touch control electrodes 213, for example. The third touch control electrodes 213 are connected as a whole using the touch control connection electrode 191.

By using the touch control connection electrode 191 to connect a plurality of reusable electrodes or/and third touch control electrodes 213 as a single touch control electrode, it can choose an area and range to dispose the touch control electrode, thereby enlarging the scope of possible In-Cell touch control structures and the scope of application thereof and improving touch control performance.

Referring to FIGS. 1, 2 and 6, in some embodiments, the second metal layer includes a plurality of touch control traces 192 and a plurality of touch control connection electrodes 191. Each of the touch control traces 192 connects to a corresponding touch control electrode or touch control connection electrode 191.

Specifically, a structure with an In-Cell touch control ability belongs to self-capacitive-type touch control, for example. The touch control electrodes are touch control sensing electrodes. The touch control traces 192 are touch control driving traces. The touch control traces 192 connect to corresponding touch control electrodes.

Referring to FIGS. 3 and 6, in some embodiments, the array substrate 10 includes a third metal layer 17, which is located between the substrate 11 and the second metal layer 19. A second insulating layer 18 is provided between the second metal layer 19 and the third metal layer 17. The third metal layer 17 includes a plurality of touch control traces 173 and the source 171 (or the source 172) and the drain 172 (or the drain 171) of the third thin-film transistor 100. Each touch control trace 173 connects to a corresponding touch control electrode.

Specifically, a structure with an In-Cell touch control ability belongs to self-capacitive-type touch control, for example. The touch control electrodes are touch control sensing electrodes. The touch control traces 173 are touch control driving traces.

The touch control traces 173 connect to corresponding touch control electrodes.

By deploying the touch control traces at a same layer or a different layer of the source 171 (or the source 172) and the drain 172 (or the drain 171), the scope of possible In-Cell touch control structures and the scope of application thereof are enlarged.

The present application provides a method for manufacturing a micro-LED display panel 1000. Referring to FIGS. 1 and 6, the manufacturing method includes the following steps.

Step S1— forming a third metal layer 17 at a side of a substrate 11, wherein the third metal layer 17 includes a source 171 (or a source 172) and a drain 172 (or a drain 171) of a thin-film transistor 100;

Step S2— forming a second insulating layer 18 on the third metal layer 17, wherein the second insulating layer includes a first via hole 181;

Step S3— forming a second metal layer 19 on the second insulating layer 18, wherein the second metal layer 19 includes a plurality of touch control connection electrodes 191 and a plurality of touch control traces 192;

Step S4— forming a first insulating layer 20 on the second metal layer 19, wherein the first insulating layer 20 includes a second via hole 201 and a third via hole 202, and orthographic projection of the second via hole 201 on the substrate 11 at least partially overlaps with orthographic projection of the first via hole 181 on the substrate 11;

Step S5— forming a first metal layer 21 on the first insulating layer, wherein the first metal layer 21 includes a plurality of first connection electrodes 211 and a plurality of second connection electrodes 212, the first connection electrode 211 connects to the source 171 (or the source 172) or the drain 172 (or the drain 171) of the thin-film transistor 100 via the first via hole 181 and the second via hole 201, at least one of the plurality of first connection electrodes 211 and the plurality of second connection electrodes 212 are reusable electrodes, each of the reusable electrodes drives a corresponding micro-LED 111 to emit light at a display stage, each of the reusable electrodes is reused as a touch control electrode at a touch control stage, each touch control electrode includes some of the reusable electrodes connected to each other, each of the touch control connection electrodes 191 is connected between two corresponding reusable electrodes, and the touch control traces 192 connect to the touch control connection electrodes corresponding to the touch control electrodes 191; and

Step S6 — mounting micro-LEDs 111 such that each of the first connection electrodes 211 and a corresponding second connection electrode 212 connect to a corresponding micro-LED 111.

In some embodiments of the manufacturing method, the method further includes forming a buffer layer 12 at a side of the substrate 11 and forming the thin-film transistor 100 on the buffer layer 12, wherein the thin-film transistor includes an active layer 13, a gate insulating layer 14, a gate 15, an insulating interlayer 16, a source 171 (or a source 172), a drain 172 (or a drain 171), and wherein the structure of the thin-film transistor 100 is not limited, and for example, the thin-film transistor 100 may be of a top-gate type or of a bottom-gate type.

In some embodiments of the manufacturing method, the touch control traces may be disposed on the third metal layer 17. Referring to FIG. 3, the third metal layer 17 include the touch control traces 173.

It is noted that in above manufacturing method, the micro-LEDs are mounted on the array substrate 10, and the ways to electrically connect each micro-LEDs 111 to a corresponding first connection electrode 211 and a corresponding second connection electrode 212 include, but is not limited to, using a connection material, which can be a solder paste made of tin.

By above manufacturing method, it can manufacture a high-performance micro-LED display panel 1000 with an In-Cell touch control ability.

The present application further provides a display device 3000. Referring to FIG. 7, the display device 3000 includes any type of above-described micro-LED display panels 1000. The display device may further include, but is not limited thereto, other components 2000 including a housing, a protective component and etc.

The present application provides a micro-LED display panel with an In-Cell touch control structure. By integrating a touch function into the micro-LED display panel without a need of additional lamination with touch control components, the thickness and cost of the micro-LED display panel can be reduced, thereby widening the scope of application of the micro-LED display panel.

In the above embodiments, different emphasis is placed on respective embodiments, and reference may be made to related depictions in other embodiments for portions not detailed in a certain embodiment.

Hereinbefore, the embodiments of the present application are introduced in detail, the principles and implementations of the present application are set forth herein with reference to specific examples, descriptions of the above embodiments are merely served to assist in understanding the technical solutions and essential ideas of the present application. Those having ordinary skill in the art should understand that they still can modify technical solutions recited in the aforesaid embodiments or equivalently replace partial technical features therein; these modifications or substitutions do not make essence of corresponding technical solutions depart from the spirit and scope of technical solutions of embodiments of the present application.

1. A micro light-emitting diode (micro-LED) display panel, comprising:
a plurality of micro-LEDs; and
an array substrate, comprising a first metal layer that comprises a plurality of first connection electrode and a plurality of second connection electrodes, each of the first connection electrodes and a corresponding second connection electrode connecting to a corresponding micro-LED,
wherein at least one of the plurality of first connection electrodes and the plurality of second connection electrodes are reusable electrodes, and each of the reusable electrodes drives the corresponding micro-LED to emit light at a display stage; and
wherein each of the reusable electrodes is reused as a touch control electrode at a touch control stage.

2. The micro-LED display panel according to claim 1, wherein at the touch control stage, at least a part of the plurality of second connection electrodes are reused as the touch control electrodes and the plurality of first connection electrodes are not reused as the touch control electrodes.

3. The micro-LED display panel according to claim 1, wherein at the touch control stage, both the plurality of first connection electrodes and the plurality of second connection electrodes are reused as the touch control electrodes.

4. The micro-LED display panel according to claim 3, wherein the touch control electrodes comprise sensing touch control electrodes and receiving touch control electrodes, and at the touch control stage, at least a part of the plurality of first connection electrodes are reused as the sensing touch control electrodes and at least a part of the plurality of second connection electrodes are reused as the receiving touch control electrodes.

5. The micro-LED display panel according to claim 2, wherein the touch control electrodes comprise sensing touch control electrodes and receiving touch control electrodes, and at the touch control stage, at least a part of the plurality of second connection electrodes are reused as the sensing touch control electrodes and the receiving touch control electrodes.

6. The micro-LED display panel according to claim 1, wherein the first metal layer further comprises third touch control electrodes.

7. The micro-LED display panel according to claim 1, wherein each touch control electrode comprises some of the reusable electrodes connected to each other.

8. The micro-LED display panel according to claim 7, wherein the array substrate comprises a substrate and a second metal layer, the second metal layer is located between the substrate and the first metal layer, a first insulating layer is provided between the first metal layer and the second metal layer, the second metal layer comprises a plurality of touch control connection electrodes, and each of the touch control connection electrodes is connected between two corresponding reusable electrodes.

9. A method for manufacturing a micro light-emitting diode (micro-LED) display panel, comprising:
forming a third metal layer at a side of a substrate, wherein the third metal layer comprises a source and a drain of a thin-film transistor;
forming a second insulating layer on the third metal layer, wherein the second insulating layer comprises a first via hole;
forming a second metal layer on the second insulating layer, wherein the second metal layer comprises a plurality of touch control connection electrodes and a plurality of touch control traces;
forming a first insulating layer on the second metal layer, wherein the first insulating layer comprises a second via hole and a third via hole, and orthographic projection of the second via hole on the substrate at least partially overlaps with orthographic projection of the first via hole on the substrate;
forming a first metal layer on the first insulating layer, wherein the first metal layer comprises a plurality of first connection electrodes and a plurality of second connection electrodes, the first connection electrode connects to the source or the drain of the thin-film transistor via the first via hole and the second via hole, at least one of the plurality of first connection electrodes and the plurality of second connection electrodes are reusable electrodes, each of the reusable electrodes drives a corresponding micro-LED to emit light at a display stage, each of the reusable electrodes is reused as a touch control electrode at a touch control stage, each touch control electrode comprises some of the reusable electrodes connected to each other, each of the touch control connection electrodes is connected between two corresponding reusable electrodes, and the touch control traces connect to the touch control connection electrodes corresponding to the touch control electrodes; and
mounting micro-LEDs such that each of the first connection electrodes and a corresponding second connection electrode connect to a corresponding micro-LED.

10. A display device, comprising a micro light-emitting diode (micro-LED) display panel, which comprises:
a plurality of micro-LEDs; and
an array substrate, comprising a first metal layer that comprises a plurality of first connection electrode and a plurality of second connection electrodes, each of the first connection electrodes and a corresponding second connection electrode connecting to a corresponding micro-LED,
wherein at least one of the plurality of first connection electrodes and the plurality of second connection electrodes are reusable electrodes, and each of the reusable electrodes drives the corresponding micro-LED to emit light at a display stage; and
wherein each of the reusable electrodes is reused as a touch control electrode at a touch control stage.

11. The display device according to claim 10, wherein at the touch control stage, at least a part of the plurality of second connection electrodes are reused as the touch control electrodes and the plurality of first connection electrodes are not reused as the touch control electrodes.

12. The display device according to claim 10, wherein at the touch control stage, both the plurality of first connection electrodes and the plurality of second connection electrodes are reused as the touch control electrodes.

13. The display device according to claim 12, wherein the touch control electrodes comprise sensing touch control electrodes and receiving touch control electrodes, and at the touch control stage, at least a part of the plurality of first connection electrodes are reused as the sensing touch control electrodes and at least a part of the plurality of second connection electrodes are reused as the receiving touch control electrodes.

14. The display device according to claim 11, wherein the touch control electrodes comprise sensing touch control electrodes and receiving touch control electrodes, and at the touch control stage, at least a part of the plurality of second connection electrodes are reused as the sensing touch control electrodes and the receiving touch control electrodes.

15. The display device according to claim 10, wherein the first metal layer further comprises third touch control electrodes.

16. The display device according to claim 10, wherein each touch control electrode comprises some of the reusable electrodes connected to each other.

17. The display device according to claim 16, wherein the array substrate comprises a substrate and a second metal layer, the second metal layer is located between the substrate and the first metal layer, a first insulating layer is provided between the first metal layer and the second metal layer, the second metal layer comprises a plurality of touch control connection electrodes, and each of the touch control connection electrodes is connected between two corresponding reusable electrodes.
